(19) United States
(12) Patent Application Publication
(10) Pub. No.: US 2010/0210068 A1
(43) Pub. Date: Aug. 19, 2010

(54) Method of forming phase change memory device

(75) Inventors: Won-jun Lee, Seoul (KR); Jin-woo Park, Seoul (KR); Byoung-moon Yoon, Suwon-si (KR); Cheol-woo Park, Seoul (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/591,772

(22) Filed: Dec. 1, 2009

(30) Foreign Application Priority Data
Feb. 19, 2009 (KR) 10-2009-0013997

(51) Int. Cl. H01L 21/06

(52) U.S. Cl. 438/102; 257/E21.068

(57) ABSTRACT

Provided is a method of forming a phase change memory device, the method including washing and rinsing a phase change device structure. A phase change material layer may be formed on a semiconductor substrate. The phase change material layer may be etched so as to form a phase change device structure. The semiconductor substrate on which the phase change device structure is formed may be washed using a washing solution including a reducing agent containing fluorine (F), a pH controller, a dissolution agent and water. In addition, the semiconductor substrate on which the washing is performed may be rinsed.

### CROSS-REFERENCE TO RELATED APPLICATIONS

This application claims priority under 35 USC §119 to Korean Patent Application No. 10-2009-0013997, filed on Feb. 19, 2009, in the Korean Intellectual Property Office (KIPO), the entire contents of which are incorporated herein by reference.

### BACKGROUND

1. Field

Example embodiments relate to a method of forming a semiconductor device, and more particularly, to a method of etching chalcogenide-based material and washing a semiconductor substrate.

2. Description of the Related Art

Phase change memories store and read information by using a resistance difference due to a phase change of a material. An access time of a phase change memory is 103 times shorter than that of a flash memory that is an example nonvolatile memory. The phase change memory can operate at a low voltage like a dynamic random access memory (DRAM), and can read and write information like a static random access memory (SRAM). Because the phase change memory can have a relatively simple cell structure, the device size of the phase change memory may be reduced up to that of DRAM.

In addition, because the phase change memory is a memory device using a resistance difference due to a phase change of a material instead of charge accumulation, the phase change memory is not affected by cosmos radiant rays or electromagnetic waves. The phase change memory can write and delete information at 1,010 times or more. Data stored at one time can be retained in the phase change memory for 20 years or more. Phase change memories are attracting attention as the next generation of nonvolatile memories due to their nonvolatile properties, a lower threshold voltage, a smaller access time, and/or nondestructive reading.

When a dry etch is performed on a phase change material in order to obtain a phase change device structure, an etch residual product is generated. If the etch residual product is removed using a conventional organic strip solution, the phase change device structure may be etched together with the phase change material to be detached.

### SUMMARY

Example embodiments provide a method of forming a phase change memory device, the method including etching and washing a phase change material, wherein an etch residual product is removed without affecting the phase change material.

According to example embodiments, a method of forming a phase change memory device may include forming a phase change material layer on a semiconductor substrate. The phase change material layer may be etched so as to form a phase change device structure. The semiconductor substrate may be washed by using a washing solution including a reducing agent containing fluorine (F), a potential of hydrogen (pH) controller, a dissolution agent and water. In addition, the semiconductor substrate on which the washing is performed may be rinsed.

The reducing agent containing fluorine (F) may include hydrofluoric acid or ammonium fluoride. The pH controller may include ammonium chloride. The dissolution agent may include acetic acid (CH₃COOH), phosphoric acid (H₃PO₄) or isopropyl alcohol (IPA). The washing solution may include about 0.05 to 1 wt % of the reducing agent containing fluorine (F), about 0.10 to 2 wt % of the pH controller, about 4 wt % to 20 wt % of the dissolution solution, and about 77 wt % to 95.85% of the water.

The phase change material layer may include chalcogenide. The phase change material layer may include germanium (Ge)-antimony (Sb)-tellurium (Te) (GST). Rinsing the semiconductor substrate may include using deionized water or isopropylalcohol (IPA). The rinsing may be performed for about 1 to 3 minutes. The method may further include forming a capping layer covering the phase change device structure and forming an interlayer insulating film on the capping layer, and forming a contact through the interlayer insulating film and the capping layer so as to connect the contact to the phase change material layer of the phase change device structure.

Forming the phase change structure may further include forming a phase change structure layer by forming sequentially the phase change material layer, an upper electrode layer and a hard mask layer on a lower electrode of the semiconductor substrate.

According to example embodiments, a method of forming a phase change memory device may include forming a phase change structure layer including sequentially forming a phase change material layer, an upper electrode layer and a hard mask layer on a lower electrode of a semiconductor substrate. The phase change structure layer may be etched so as to form a phase change device structure. The semiconductor substrate may be washed by using a washing solution including about 0.05 to 1 wt % of hydrogen fluoride or ammonium fluoride, about 0.10 to 2 wt % of ammonium hydroxide, about 4 to 20 wt % of acetic acid, phosphoric acid or IPA, and about 77 wt % to 95.85% of the water. The semiconductor substrate on which the washing is performed may be rinsed. A capping layer covering the phase change device structure may be formed and an interlayer insulating film may be formed on the capping layer. In addition, a contact may be formed through the interlayer insulating layer and the capping layer so as to connect the contact to the phase change material layer of the phase change device structure.

In example embodiments, the reducing agent containing fluorine (F) may include hydrofluoric acid or ammonium fluoride. The pH controller may include ammonium chloride. The dissolution agent may include acetic acid (CH₃COOH), phosphoric acid (H₃PO₄) or isopropyl alcohol (IPA). The phase change material layer may include chalcogenide. The phase change material layer may include germanium (Ge)-antimony (Sb)-tellurium (Te) (GST). Rinsing the semiconductor substrate may include using deionized water or isopropylalcohol (IPA). Rinsing the semiconductor substrate may include rinsing for about 1 to 3 minutes. The capping layer covering the phase change device structure and the interlayer insulating film on the capping layer may be formed after rinsing the semiconductor substrate.

### BRIEF DESCRIPTION OF THE DRAWINGS

Example embodiments will be more clearly understood from the following detailed description taken in conjunction with the accompanying drawings in which:

FIGS. 1A through 1D are cross-sectional views for explaining a method of forming a phase change memory device, according to example embodiments;

FIG. 2 is a plan scanning electron microscopy (SEM) image illustrating the result when a phase change device structure is etched, and a semiconductor substrate is processed for 1 minute by a hydrofluoric acid (HF) solution;

FIG. 3 is a plan SEM image illustrating the result when a phase change device structure using GST as a phase change layer is etched, and a semiconductor substrate may be washed using a washing solution for about 3 minutes at a temperature of about 25° C.

FIGS. 4A and 4B are plan SEM images illustrating the result when a phase change device structure using GST is etched, subsequent operations are performed, and a sectional test piece is processed using a washing solution;

FIG. 5 is a graph for showing a measurement result of a residual product of a semiconductor substrate which is washed, according to a rinse time;

FIG. 6 is a graph for showing a test result with respect to wafers of a phase change memory device of the cases where rinsing is performed for about 30 seconds after washing is performed, and rinsing is performed for about 2 minutes after washing is performed;

FIG. 7A is a graph for showing a distribution of resistance of a phase change resistance device when a phase change device structure is etched, but not washed; and

FIG. 7B is a graph for showing a distribution of resistance of a phase change resistance device when a phase change device structure is etched and washed.

### DETAILED DESCRIPTION OF EXAMPLE EMBODIMENTS

Reference will now be made in detail to example embodiments which are illustrated in the accompanying drawings. In this regard, example embodiments may have different forms and should not be construed as being limited to the descriptions set forth herein. Accordingly, example embodiments are merely described below, by referring to the figures, to explain aspects of the present description. In the drawings, the thicknesses of layers and regions are exaggerated for clarity. Like reference numerals refer to the like elements throughout.

It will be understood that, although the terms first, second, third etc. may be used herein to describe various elements, these elements should not be limited by these terms. These terms are used to distinguish one element from another. Thus, a first element discussed below could be termed a second element without departing from the teachings of example embodiments. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular example embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

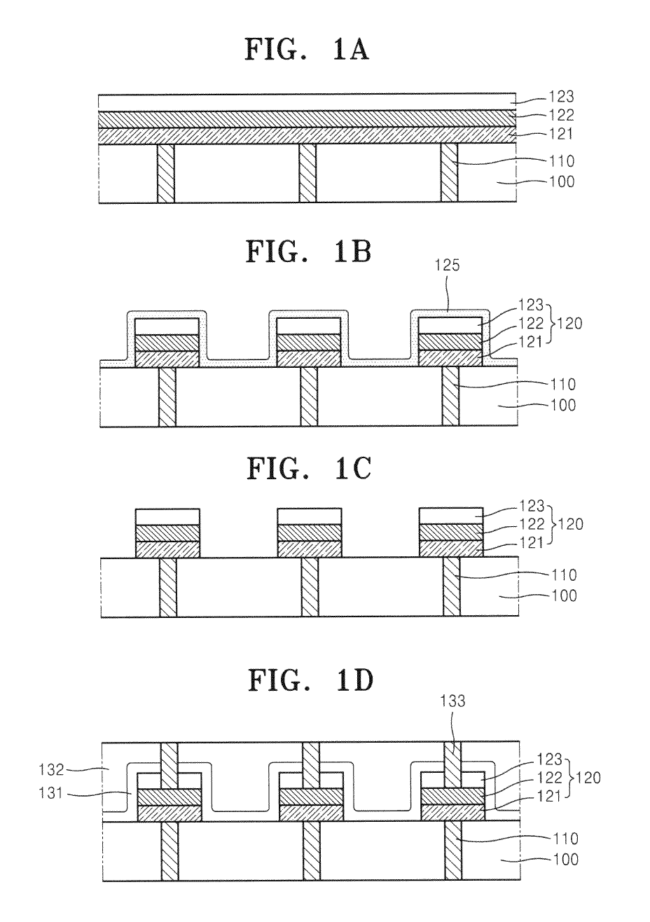

FIGS. 1A through 1D are cross-sectional views for explaining a method of forming a phase change memory device, according to example embodiments. Referring to FIG. 1A, a phase change material layer 121, an upper electrode layer 122 and a hard mask layer 123 may be sequentially formed on a semiconductor substrate 100 in which a lower electrode 110 is formed. The lower electrode 110 may be formed of, for example, titanium nitride (TiN) or titanium-aluminum nitride (TiAlN).

The phase change material layer 121 may be formed of chalcogenide. For example, the phase change material layer 121 may be formed of germanium (Ge)-antimony (Sb)-tellurium (Te) (GST). As another example, the phase change material layer 121 may be formed of at least one selected from the group consisting of germanium (Ge)-tellurium (Te) (Ge—Te), arsenic (As)-antimony (Sb)-tellurium (Te) (As—Sb—Te), tin (Sn)-antimony (Sb)-tellurium (Te) (Sn—Sb—Te), silicon-germanium (Ge)-antimony (Sb)-tellurium (Te) (Si—Ge—Sb—Te), tin (Sn)-indium (In)-antimony (Sb)-tellurium (Te) (Sn—In—Sb—Te), nitrogen (N)-germanium (Ge)-antimony (Sb)-tellurium (Te) (N—Ge—Sb—Te), arsenic (As)-germanium (Ge)-antimony (Sb)-tellurium (Te) (As—Ge—Sb—Te), tantalum (Ta), niobium (Nb) or vanadium (V)-antimony (Sb)-tellurium (Te) (Ta, Nb or V—Sb—Te), tungsten (W), molybdenum (Mo) or chromium (Cr)-antimony (Sb)-tellurium (Te) (W, Mo or Cr—Sb—Te), tantalum (Ta), niobium (Nb) or vanadium (V)-antimony (Sb)-selenium (Se) (Ta, Nb or V—Sb—Se), or tungsten (W), and molybdenum (Mo) or chromium (Cr)-antimony (Sb)-selenium (Se) (W, Mo or Cr—Sb—Se).

The upper electrode layer 122 may be formed of titanium nitride (TiN) or titanium aluminum nitride (TiAlN), similar to the lower electrode 110. The hard mask layer 123 may be formed of a silicon oxide, e.g., plasma enhanced chemical vapor deposition silicon oxide (PECVD silicon oxide).

When the phase change memory according to example embodiments uses a diode as a switching device, a PN diode (not shown) connected to the lower electrode 110 may be formed on the semiconductor substrate 100. When the phase change memory uses a transistor as a switching device, a gate electrode (not shown), and source/drain (not shown) may be formed on the semiconductor substrate 100, and the lower electrode 110 may be connected to one of source/drain regions via a contact.

Referring to FIG. 1B, a phase change device structure 120 may be formed by etching the phase change material layer 121, the upper electrode layer 122 and the hard mask layer 123. To achieve this, a photoresist pattern (not shown) may be formed on the hard mask layer 123, and a hard mask layer pattern 123 may be formed by etching the hard mask layer pattern 123. The phase change device structure 120 may be formed etching the upper electrode layer 122 and the phase change material layer 121 by using the hard mask layer pattern 123 as an etch mask. In example embodiments, the phase change material layer 121 may be etched using a gas including CxHyFz (x≧1, y≧0, z≧1).

After the phase change device structure 120 is etched, an etch residual product 125 may accumulate on the phase change device structure 120 and the semiconductor substrate 100. The etch residual product 125 may be an organic metallic polymer including a carbon (C) component, an oxygen component, and a metallic component.

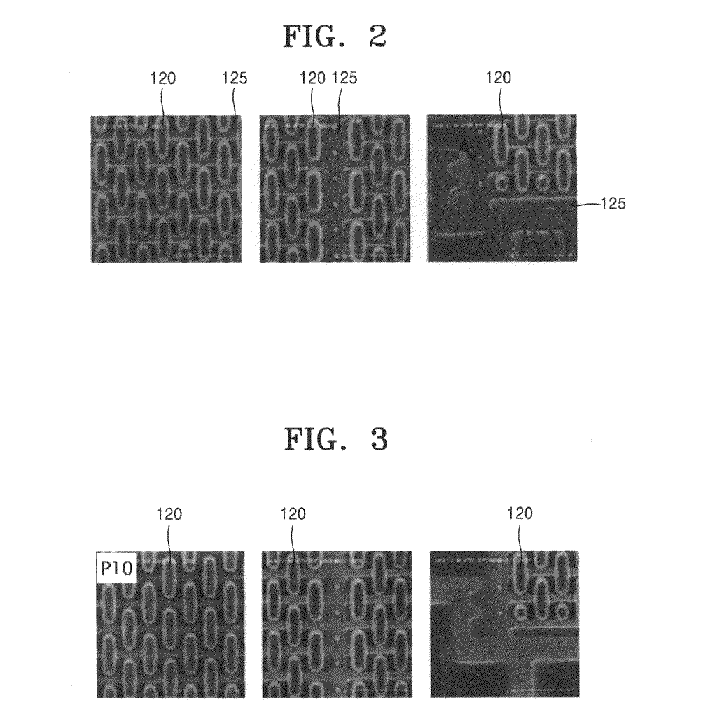

FIG. 2 is a plan scanning electron microscopy (SEM) image illustrating the result when the phase change device structure 120 is etched, and the semiconductor substrate 100 is processed for about 1 minute by a hydrofluoric acid (HF) solution. Referring to FIG. 2, uneven portions between patterns are portions generated from the etch residual product 125 detached from the semiconductor substrate 100 by a hydrofluoric acid (HF) solution and conglomerated on the semiconductor substrate 100 rather than being dissolved in the hydrofluoric acid (HF) solution.

Thus, from FIG. 2, the etch residual product 125 may be generated after the phase change device structure 120 is etched. The hydrofluoric acid (HF) may not dissolve the etch residual product 125, and thus, removing the etch residual product 125 by using only the hydrofluoric acid (HF) may be sufficient.

FIG. 1C is a cross-sectional view of the result when the etch residual product 125 is removed by processing the semiconductor substrate 100 including the phase change device structure 120 formed thereon by using a washing solution. A mixture solution of hydrofluoric acid (HF), ammonium hydroxide (NH₄OH), acetic acid (CH₃COOH) and water (H₂O) may be used as the washing solution. In example embodiments, a mixing ratio of hydrofluoric acid (HF):ammonium hydroxide (NH₄OH):acetic acid (CH₃COOH):water (H₂O) of the washing solution may be about 1:2:50:500. The semiconductor substrate 100 may be washed using the washing solution, and rinsed using deionized water or isopropyl alcohol (IPA). A bath or single wafer-type spin spray method may be used in rinsing. Rinsing may be performed for about 2-3 minutes at a temperature of about 25° C.

The hydrofluoric acid (HF) may detach the etch residual product 125 from the phase change device structure 120 and the semiconductor substrate 100, as described with reference to FIG. 2. In example embodiments, the hydrofluoric acid (HF) may etch a surface of the phase change material layer 121. For example, antimony (Sb) of the phase change material layer 121 may be more easily melted by the hydrofluoric acid (HF). Thus, the concentration of the hydrofluoric acid (HF) must be appropriately maintained so that the phase change device structure 120 is not corroded during washing. Alternatively, ammonium fluoride (NH₄F) may be used instead of the hydrofluoric acid (HF).

The acetic acid (CH₃COOH) changes the state of the etch residual product 125 so that the etch residual product 125 may be more easily dissolved in water. The ammonium hydroxide (NH₄OH) controls the potential of hydrogen (pH) of the washing solution, and facilitates the dissolution of the etch residual product 125.

FIG. 3 is a plan SEM image of where the phase change device structure 120 using GST as a phase change layer is etched, and the semiconductor substrate 100 may be washed using the washing solution for about 3 minutes at a temperature of about 25° C. The plan SEM image of FIG. 3 shows that the etch residual product 125 of FIG. 2 that is conglomerated is removed from a surface of the semiconductor substrate 100.

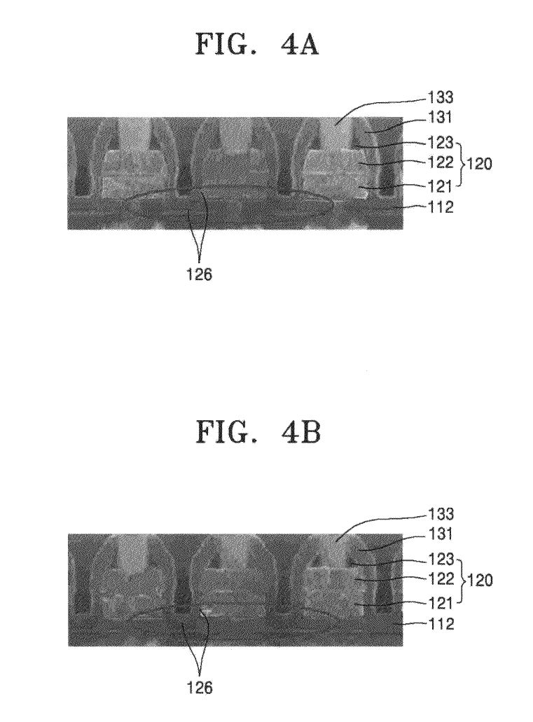

FIGS. 4A and 4B are plan SEM images illustrating the result when the phase change device structure 120 using GST is etched, subsequent operations are performed, and a sectional test piece is processed using the washing solution. FIG. 4A illustrates when washing is not performed after the phase change device structure 120 is etched. FIG. 4B illustrates when washing is performed for about 3 minutes at a temperature of about 25° C.

In FIG. 4A, gaps are clearly seen at boundaries 126 between the phase change device structure 120 including the phase change material layer 121, the upper electrode layer 122 and the hard mask layer pattern 123, and a capping layer 131 covering the phase change device structure 120, and between a lower insulating layer 112 and the capping layer 131. However, in FIG. 4B, gaps are unclearly seen at the boundaries 126 between the phase change device structure 120 and the capping layer 131, and between the lower insulating layer 112 and the capping layer 131. An interlayer insulating film 132 connected to the upper electrode layer 122 may also be formed. The reference number 133 is an upper contact which is electrically connected to upper electrode layer 122 through the hard mask layer 123 and the capping layer 131.

The gaps seen at the boundaries 126 of FIG. 4A is a place on which the etch residual product 125 generated after the phase change device structure 120 is etched and removed by processing the semiconductor substrate 100 with the washing solution, thereby exposing the semiconductor substrate 100. In FIG. 4B, because the capping layer 131 is formed by etching the phase change device structure 120 and removing the etch residual product 125 by washing, the gaps are not seen unlike in FIG. 4A.

A GST and a PECVD silicon oxide layer may be etched by a thickness less than about 10 Å during washing. Thus, washing may remove the etch residual product 125 without affecting the phase change device structure 120. Because washing is performed at a normal temperature, heat is not applied to the semiconductor substrate 100, and a washing apparatus may be simplified. In addition, a reduction in the lifetime of the washing solution due to the high temperature of the washing solution may not occur.

When a test is performed on the phase change memory device on which washing is performed, a single bit fail may occur in a wafer many times. In order to determine the cause of the single bit fail, the eluting amounts of antimony (Sb), germanium (Ge) and tellurium (Te) are measured in a washing solution. As a result of measurement, several ppb of antimony (Sb), germanium (Ge) and tellurium (Te) are detected. Thus, the signal bit fail does not occur due to the washing solution with respect to GST.

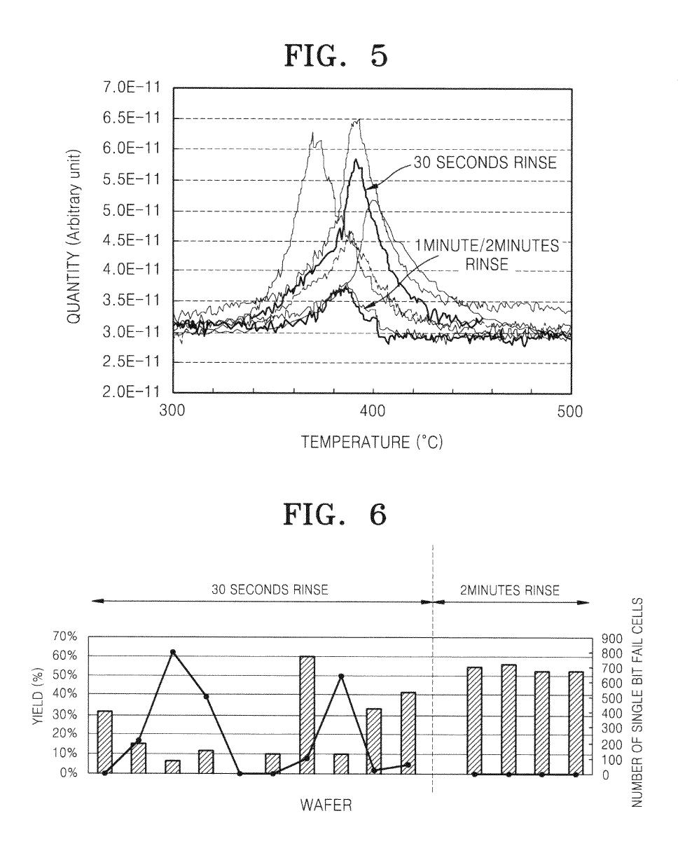

FIG. 5 is a graph for showing a measurement result of a residual product of a semiconductor substrate on which washing is performed, according to a rinse time. The residual product is detached in a gaseous form from the semiconductor substrate by heating the semiconductor substrate, and the amount of the residual product is measured. The residual product is C₃H₄.

FIG. 5 illustrates a plot when the amount of C₃H₄ is measured according to a temperature when rinsing is performed for about 30 seconds after washing is performed, and plots when the amount of C₃H₄ is measured according to a temperature when rinsing is performed for about 1 and 2 minutes, respectively, after washing is performed. From the graph of FIG. 5, the amount of C₃H₄ when rinsing is performed for about 30 seconds after washing is performed is lower than the amount of C₃H₄ when rinsing is performed for about 1 and 2 minutes after washing is performed. Thus, when the rinse time is not sufficient after washing is performed, the residual product remains on the semiconductor substrate, and thus, the residual product affects the GST.

FIG. 6 is a graph for showing a test result with respect to wafers of a phase change memory device when rinsing is performed for about 30 seconds after washing is performed, and rinsing is performed for about 2 minutes after washing is performed. Bars show the yields of dies that normally operates on each wafer, and lines show the number of cells where a single bit fail occurs on each wafer.

In FIG. 6, a ratio of the wafers when rinsing is performed for 30 seconds after washing is performed is relatively low, and a variation width of the ratio is relatively great. However, a ratio of the wafers when rinsing is performed for 2 minutes after washing is performed is relatively low, and a variation width of the ratio is relatively narrow to exhibit consistency, because the signal bit fail is removed due to washing and rinsing.

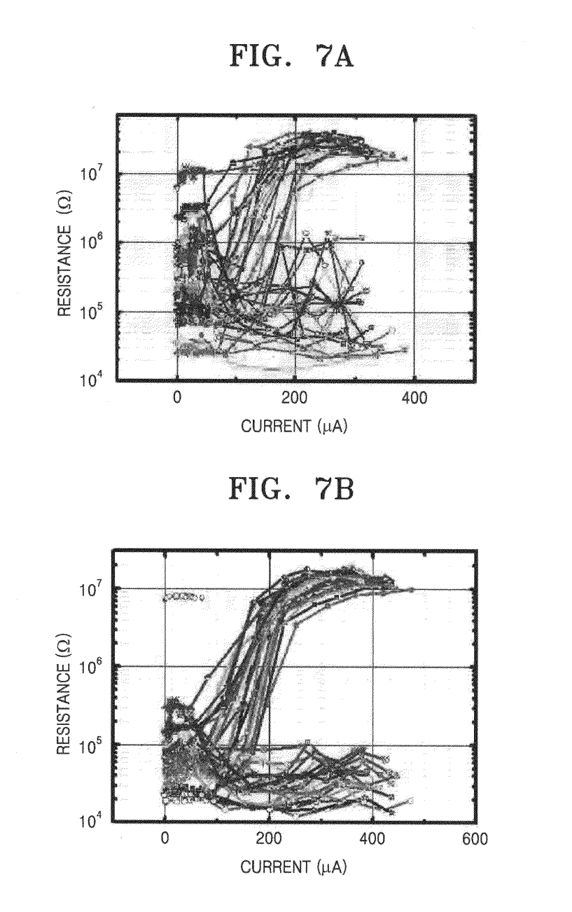

FIGS. 7A and 7B are graphs for showing distributions of resistance of phase change resistance devices in the case of set and reset statuses. FIG. 7A illustrates when a phase change device structure is etched and washing is not performed. FIG. 7B illustrates when the phase change device structure is etched and rinsed.

Referring to FIGS. 7A and 7B, when the phase change device structure is etched, and washing is not performed, resistance values are widely distributed in the case of set and reset statuses. However, when the phase change device structure is etched, and washing and rinsing are performed, resistance values are uniformly distributed in the case of set and rest statuses. Thus, an etch residual product generated after the phase change device structure is etched may be removed by washing and rinsing, and thus, the resistance of the phase change resistance device may be uniformly distributed, thereby increasing the reliability of the phase change memory device.

Referring to FIG. 1D, the phase change device structure 120 may be formed, washing and rinsing may be performed, and the capping layer 131, the interlayer insulating film 132, and an upper contact 133 connected to the upper electrode layer 122 may be formed. Forming a wiring, e.g., a bit line (not shown), is omitted.

In example embodiments, a phase change material layer and an upper electrode layer may be simultaneously etched using a hard mask. Alternatively, the phase change material layer and the upper electrode layer may be separately patterned. In example embodiments, washing may be performed after the phase change material layer is etched. Alternatively, washing may be performed after the upper electrode layer is etched. In addition, washing and rinsing may be performed by using various other methods in order to form a phase change device structure.

According to example embodiments, the resistance of the phase change device is uniformly distributed by forming and washing the phase change structure, thereby increasing the reliability of the phase change memory device. In addition, organic material attached to the semiconductor substrate is removed by rinsing for a predetermined or given time period, and thus, the single bit fail of the phase change memory device may be removed.

According to example embodiments, residual products generated after etching may be removed by etching, washing and rinsing the phase change device structure, and thus, the resistance of the phase change resistance device may be uniformly distributed. The single bit fail blocking the operation of cells may be prevented or reduced, thereby increasing the reliability of the phase change memory device.

While the inventive concept has been particularly shown and described with reference to example embodiments thereof, it will be understood that various changes in form and details may be made therein without departing from the spirit and scope of the following claims.

1. A method of forming a phase change memory device, the method comprising:
forming a phase change material layer on a semiconductor substrate:
forming a phase change device structure by etching the phase change material layer;
washing the semiconductor substrate by using a washing solution including a reducing agent containing fluorine (F), a pH controller, a dissolution agent and water; and
rinsing the semiconductor substrate on which the washing is performed.

2. The method of claim 1, wherein the reducing agent containing fluorine (F) includes hydrofluoric acid or ammonium fluoride.

3. The method of claim 1, wherein the pH controller includes ammonium chloride.

4. The method of claim 1, wherein the dissolution agent includes acetic acid (CH₃COOH), phosphoric acid (H₃PO₄) or isopropyl alcohol (IPA).

5. The method of claim 1, wherein the washing solution includes about 0.05 to 1 wt % of the reducing agent containing fluorine (F), about 0.10 to 2 wt % of the pH controller, about 4 wt % to 20 wt % of the dissolution solution, and about 77 wt % to 95.85% of the water.

6. The method of claim 1, wherein the phase change material layer includes chalcogenide.

7. The method of claim 1, wherein the phase change material layer includes germanium (Ge)-antimony (Sb)-tellurium (Te) (GST).

8. The method of claim 1, wherein rinsing the semiconductor substrate includes using deionized water or isopropylalcohol (IPA).

9. The method of claim 1, wherein rinsing the semiconductor substrate includes rinsing for about 1 to 3 minutes.

10. The method of claim 1, further comprising:
forming a capping layer covering the phase change device structure and forming an interlayer insulating film on the capping layer; and
forming a contact through the interlayer insulating film and the capping layer so as to connect the contact to the phase change material layer of the phase change device structure.

11. The method of claim 1, wherein forming the phase change structure further comprises forming a phase change structure layer by forming sequentially the phase change material layer, an upper electrode layer and a hard mask layer on a lower electrode of the semiconductor substrate.

12. A method of forming a phase change memory device, the method comprising:
forming a phase change structure layer including forming sequentially a phase change material layer, an upper electrode layer and a hard mask layer on a lower electrode of a semiconductor substrate;
forming a phase change device structure by etching the phase change structure layer;
washing the semiconductor substrate by using a washing solution including about 0.05 to 1 wt % of hydrogen fluoride or ammonium fluoride, about 0.10 to 2 wt % of ammonium hydroxide, about 4 to 20 wt % of acetic acid, phosphoric acid or IPA, and about 77 wt % to 95.85% of the water;
rinsing the semiconductor substrate on which the washing is performed;
forming a capping layer covering the phase change device structure and forming an interlayer insulating film on the capping layer; and
forming a contact through the interlayer insulating film and the capping layer so as to connect the contact to the phase change material layer of the phase change device structure.

13. The method of claim 12, wherein the reducing agent containing fluorine (F) includes hydrofluoric acid or ammonium fluoride.

14. The method of claim 12, wherein the pH controller includes ammonium chloride.

15. The method of claim 12, wherein the dissolution agent includes acetic acid (CH₃COOH), phosphoric acid (H₃PO₄) or isopropyl alcohol (IPA).

16. The method of claim 12, wherein the phase change material layer includes chalcogenide.

17. The method of claim 12, wherein the phase change material layer includes germanium (Ge)-antimony (Sb)-tellurium (Te) (GST).

18. The method of claim 12, wherein rinsing the semiconductor substrate includes using deionized water or isopropylalcohol (IPA).

19. The method of claim 12, wherein rinsing the semiconductor substrate includes rinsing for about 1 to 3 minutes.

20. The method of claim 12, wherein the capping layer covering the phase change device structure and the interlayer insulating film on the capping layer are formed after rinsing the semiconductor substrate.
